(19) United States
(12) Patent Application Publication
(10) Pub. No.: US 2024/0206075 A1
(43) Pub. Date: Jun. 20, 2024

(54) A METHOD AND DEVICE FOR PRODUCING A PRODUCT COMPRISING A SUBSTRATE WITH AT LEAST ONE PATTERNED LAYER

(71) Applicant: DP Patterning AB, Norrköping (SE)

(72) Inventors: Staffan Nordlinder, Norrköping (SE); Roman Armgarth, Norrköping (SE); Joakim Snökvist, Enstaberga (SE); Rune Groppfeldt, Oslo (NO)

(21) Appl. No.: 18/287,437

(22) PCT Filed: Apr. 19, 2022
(86) PCT No.: PCT/EP2022/060281

§ 371 Date: Oct. 18, 2023

(30) Foreign Application Priority Data
Apr. 19, 2021 (SE) 2150485-7

(51) Int. Cl. H05K 3/04

(52) U.S. Cl. CPC H05K 3/043; H05K 2203/0143; H05K 2203/0228

(57) ABSTRACT

The document relates to a method of producing a product comprising a substrate with at least one 2D-patterned layer from a multilayer material (1), wherein the multilayer material (1) is passed through at least one nip (6, 6a, 5 6b), provided by a milling cutter (51, 51a, 51b) cooperating with a patterned cliche cylinder (52, 52a, 52b), to selectively remove predetermined portions of material from at least a first layer (10) of the multilayer material (1) in accordance with a pattern of the patterned cliché cylinder (52, 52a, 52b), whereby the 2D-patterned layer is formed from the first layer (10). The method comprises: providing the multilayer material (1) comprising at least the first layer (10) and a second layer (20); feeding the multilayer material (1) through a first such nip (6, 6a) to partially, as seen in a thickness direction of the first layer (10), remove at least some of the predetermined portions of material from the first layer (10); and feeding the multilayer material (1) through a second such nip (6, 6b) to remove a remainder of said at least some of the predetermined portions of material.

### TECHNICAL FIELD

The present document relates to a method for producing a product comprising a substrate with at least one patterned layer.

### BACKGROUND

A known method of manufacturing electrical conductors and components on flexible backings or carriers is to firstly apply a thin layer (<1 mm) of conducting material, e.g. a metal or metal alloy or doped resin material, on the flexible backings or carriers, and secondly remove not wanted parts of said layer from the flexible backings or carriers by etching with chemical substances.

However, such method has several drawbacks. In particular, the process has to be done in a number of separate steps. Thus, it is only possible to perform this technique in a continuous process if the feeding rate of the material is low. Furthermore, the employed chemical substances used in this type of method is disadvantageous in terms of waste management problems and negative environmental impact.

In EP1665912 B1, there is disclosed a device and a method, wherein a cliché presses out the desired pattern on a material, e.g. in form of a continuous web or a sheet, consisting of a conducting top layer and a dielectric bottom carrier. A milling wheel mechanically removes the protruding pattern from the top layer (also referred to as the pattern layer), while the bottom carrier remains untouched. This leaves a conductive pattern on the material. The removal of material from the conducting top layer is performed simultaneously with the step of pressing out the desired pattern on the material.

Thus, EP1665912 B1 discloses a method and device that facilitates the manufacturing of electrical components in a fast and reliable way, using a single step, and which does not require etching with chemical substances. The device and method can be used to produce for example heaters, flexible circuit boards etc. The device and method have been proven in particular efficient for providing conductive patterns on materials with a conductive layer having a thickness of up to about 40 μm, e.g. a material comprising an aluminum (Al) layer having a thickness of up to about 40 μm.

U.S. Pat. No. 10,709,022 B discloses milling from two opposite sides of a flex foil with two conductive layers. The conductive layers disclosed have a thickness in a range of 5 μm to 40 μm.

However, in some applications, it would be desirable to remove material from at least one layer of material that is difficult to machine. For example, it may be desirable to remove material from at least one layer of material which requires high cutting forces to cut through the material. Also, as an example, it may be desirable to use at least one thicker and/or harder layer, for example thicker and/or harder conductive layers. Milling patterns in such hard-to-process materials, such as materials requiring high cutting forces and/or which comprises thick and/or hard layer(s), is difficult with existing methods and devices, resulting in poor quality and/or significantly reduced manufacturing speed. For some materials, such as for example Copper (Cu), difficulties of efficient milling may arise already when the copper top layer has a thickness of more than 10 μm.

Therefore, it is desirable to provide a device and method that facilitates the manufacturing of a structure/pattern on a multilayer material, in a fast and reliable way, even when the multilayer material comprises at least one conductive layer with a thickness greater than 40 μm. It is also desirable to provide a device and method that in a cost-efficient way can provide high-quality patterns on a material that requires high cutting forces to cut through the material. For example, it is desirable to provide a device and method that in a cost-efficient way can provide high-quality patterns on a material comprising a conductive layer of Copper (Cu).

### SUMMARY

It is an object of the present disclosure, to provide an improved method and device for producing a product comprising a substrate with at least one patterned layer, which eliminates or alleviates at least some of the disadvantages of the prior art.

More specific objects include providing an improved device and method that is environmentally friendly and cost-efficient, and which can provide high-quality patterns on a multilayer material, even when the multilayer material comprises at least one conductive layer having a thickness greater than 40 μm.

It is further a specific object to provide an improved device and method that is environmentally friendly and cost-efficient, and which can provide high-quality patterns on a material is difficult to machine, for example that requires high cutting forces to cut through the material.

It is further a more specific object to provide an improved device and method that is environmentally friendly and cost-efficient, and which can provide high-quality patterns in a conductive layer of Copper (Cu).

The invention is defined by the appended independent claims. Embodiments are set forth in the appended dependent claims and in the following description and drawings.

According to a first aspect, there is provided a method of producing a product comprising a substrate with at least one 2D-patterned layer from a multilayer material, wherein the multilayer material is passed through at least one nip provided by a milling cutter cooperating with a patterned cliché cylinder, to selectively remove predetermined portions of material from at least a first layer of the multilayer material in accordance with a pattern of the patterned cliché cylinder, whereby the 2D-patterned layer is formed from the first layer. The method comprises providing the multilayer material comprising at least the first layer and a second layer, feeding the multilayer material through a first such nip to partially, as seen in a thickness direction of the first layer, remove at least some of the predetermined portions of material from at least the first layer, such that said predetermined portions of material are reduced in thickness, but not entirely removed when the material is passed through said first nip, and feeding the multilayer material through a second such nip to remove a remainder of said at least some of the predetermined portions of material, such that said predetermined portions of material are entirely removed after passage of said second nip.

The multilayer material comprises at least two layers of material. The multilayer material is a flexible material. The flexible material may be provided in form of a web, such as a foil, film etc. The flexible material may be provided in form of a continious web or in form of a sheet.

The second layer may be seen to form a substrate layer or a bottom carrier layer. The second layer may be dielectric. Thus, the second layer can be seen to form said substrate.

The first layer may be seen to form a layer that is to be provided with a structure or pattern. The first layer may be conductive. The first layer may be seen to form a top layer. Alternatively, in the case the multilayer material comprises more than two layers, the first layer may be seen to form an intermediate layer. For example, the first layer may be seen to form an intermediate conductive layer sandwiched between two layers of dielectric material, for example between a dielectric substrate and a dielectric cover layer, or between a dielectric substrate and an intermediate dielectric layer.

At least one adhesive layer may be provided between the first and second layers. Thus, the multilayer material may be seen to comprise at least one adhesive layer.

A “nip” can be seen to be defined by a cliché cylinder and a cooperating milling cutter. The cliché cylinder may be mounted in fixed bearings on a stand while the milling cutter may be movably arranged in a direction to or from the patterned cliché cylinder in order to widen or shorten said nip. Alternatively, the cliché cylinder may be movable relative the milling cutter. Alternatively, both the cliché cylinder and the milling cutter may be movable relative one another. In said nip, the multilayer material can be forced against an envelope surface of the cliché cylinder, by applying a tensile stress on the running multilayer material. Thereby, at least the first layer of the multilayer material can be shaped into a three-dimensional pattern of ridges and valleys.

The term “milling cutter” is meant to include all rotating bodies having an abrading, abrasive or milling envelope surface equipped with teeth, grit or abrasive grains of, for example, sand, diamond particles or similar.

The milling cutter can be provided in form a milling cylinder. The milling cutter may be provided in form of a cylindrical milling wheel, with cutting teeth running along an axial direction of an envelope surface of the cylinder, such as helically or straight along the axial direction.

The patterned cliché cylinder can be provided in the form of a cylindrical carrier with a patterned envelope surface. The pattern comprises raised and recessed portions, which make up the pattern, such that raised portions correspond to material portions that are to be cut away and recessed portions correspond to material portions that are to be kept.

The “predetermined portions of material” are the portions of the first layer that are to be removed through the entire thickness of the first layer, in order to form a 2D pattern from the first layer.

The 2D pattern may be a pattern that varies both in a machine direction and in a cross machine direction, i.e. the pattern may be constant in neither the machine direction nor the cross machine direction.

The removal of the predetermined portions of material from the first layer is performed partially in one or several first milling steps and is completed in a subsequent milling step. Thus, the predetermined portions of material that are to be removed from the first layer can be removed in two or more milling steps. After the final milling step, at least the first layer has been cut through and predetermined portions of material have been removed from the first layer, such that at least a portion of an adjacent, underlying layer of the multilayer material is exposed. Thus, a pattern can be seen to be formed in at least the first layer of the multilayer material.

In some embodiments, it may be desirable to partially remove the predetermined portions of material evenly, as seen in the thickness direction, over the entire substrate. In other embodiments it may be desirable to remove parts of the predetermined portions of material entirely in a first step, while other parts of the predetermined portions of material are only removed partially, as seen in the thickness direction.

Consequently, by the method as described above, material is removed from at least the first layer by at least two milling steps, such that at least the first layer is cut through its entire thickness. It is understood that in addition to the first layer, that material may be removed from at least one other layer, such as for example one or several cover layers covering the first layer or one or several underlying layers of the first layer. However, at least one layer of the multilayer material is not cut through according to the pattern, i.e. the whole multilayer material is not cut through. Preferably, at least one layer of the multilayer material 1 remains substantially untouched, or only partly machined. For example, a second layer 20 forming a substrate layer may remain untouched. Thus, a maximum cutting depth is smaller than the thickness of the multilayer material.

Hence, while the present invention provides for the removal of 2D portions of one layer in at least two milling steps to provide a 2D patterned layer, it is not excluded that a further milling operation may be performed, 30 whereby the milling is performed in accordance with a different milling pattern, leading to some portion of the product being pierced.

By a method as described above, it is possible to significantly increase the milling speed and/or cutting quality in each step, while ensuring high-quality end result.

It is possible to operate with lower cutting forces as compared with known methods.

For example, by a method as described above, it is possible to produce structures/patterns on a contintious web of flexible material with a material feeding speed of about 10 meters/minute, with a pitch of about 800 μm, even when the thickness of the first layer is greater than 40 μm.

According to one embodiment, said first and second nip 6 may be formed by a patterned cliché cylinder and a milling cutter, wherein the multilayer material is passed by the patterned cliché cylinder and the milling cutter at least two times to perform at least a first milling step and a subsequent milling step.

Thus, one and the same milling cutter and patterned cliché cylinder may be used for a plurality of milling steps. The multilayer material may be passed by the same milling cutter and cliché cylinder at least two times, wherein a milling step is performed each time.

The method allows for cost savings as only one patterned cliché cylinder and one milling cutter is required. Furthermore, machining the material using the same patterned cliché cylinder and milling cutter in several subsequent milling steps, allows for application of different feed rates and/or speeds of the milling cutter in the different milling steps.

A first material feed rate of the first milling step may differ from a second material feed rate of the subsequent milling step.

A first milling cutter speed of the first milling step may differ from a second milling cutter speed of the subsequent milling step.

According to another embodiment, the first nip may be formed by a first patterned cliché cylinder and a first milling cutter, and the second nip may be formed by a second patterned cliché cylinder and a second milling cutter.

According to yet another embodiment, the first nip may be formed by a first patterned cliché cylinder and a first milling cutter, and the second nip may be formed by a second patterned cliché cylinder and the first milling cutter.

According to some embodiments, the first nip may be formed by a first patterned cliché cylinder and a first milling cutter, and the second nip may be formed by the first patterned cliché cylinder and a second milling cutter.

Thus, as an alternative of providing one patterned cliché cylinder and one milling cutter, a plurality of patterned cliché cylinders and/or a plurality of milling cutters may be provided. The plurality of patterned cliché cylinders may be designed identicially, essentially the same, or differently. The plurality of milling cutters may be designed identicially, essentially the same, or differently. Consequently, the plurality of nips may be designed identicially, essentially the same, or differently. The plurality of nips may be arranged spaced apart or adjacent one another. By providing multiple patterned cliché cylinders and/or multiple milling cutters, a higher throughput of the process can be achieved as compared with providing one and the same patterned cliché cylinder and milling cutter for a plurality of milling steps.

The first and second milling cutters may be set to operate with the same or different milling cutter speed.

The first and second milling cutters may be set to operate with the same or different rotational direction.

Thereby, the tension of the material can be optimized.

In a first milling step, the multilayer material may be passed through said first nip and in a subsequent milling step, the multilayer material may be passed through said second nip.

Further, in the first nip, the milling cutter may be set to operate with a first cutting depth. In the second nip, the milling cutter may be set to operate with a second cutting depth. The second cutting depth may be larger than the first cutting depth.

The first patterned cliché cylinder may present a first pattern dimension and the second patterned cliché cylinder may present a second pattern dimension.

The first pattern dimension may be the same as the second pattern dimension. Alternatively, the first pattern dimension may be larger than the second pattern dimension. Alternatively, the first pattern dimension may be smaller than the second pattern dimension.

Thus, the pattern of the cliché cylinder provided in the first milling step may present a first dimension and the pattern of the cliché cylinder provided in the subsequent milling step may present a second dimension that may be the same or different as compared with one another.

Milling a larger cutout portion in the first milling step than in the subsequent milling step, enables machining of thicker materials.

By milling a smaller cutout portion in a first milling step and then increasing the cutout portion in a subsequent milling step, a high-quality cut, being well-defined through the hole depth can be provided.

Further, the method may comprise, when feeding the material through the first nip, forming at least one groove in the first layer.

Thus, after the at least one first milling step, at least one groove can be seen to be formed in the first layer. The groove may have a depth corresponding to the thickness of the first layer, or a depth being smaller than the thickness of the first layer. The at least one groove can be seen to frame or circumferent a remaining portion of material that is to be removed in the subsequent milling step.

Thus, in the at least one first milling step, only one or several edge parts of at least some of the predetermined portions of material that are to be removed, may be removed from the first layer, while the remaining material is removed in the subsequent milling step. The edge parts can be seen to form a frame or perimeter of said at least some of the predetermined portions of material that are to be removed.

The multilayer material may be a flexible material, such as a foil or a film.

The multilayer material may be provided in form of a continous web or in form of a sheet.

Thus, the multilayer material may be provided from a web unwinding roll or a supply holding a plurality of sheets.

The first layer may be a conductive layer.

The first layer may be formed of one or several metals, a metal alloy or a polymer.

The first layer may be formed of Aluminum (Al), Copper (Cu), Copper Cladded Aluminum (CCA), Tin (Sn), Gold (Au), Silver (Ag), Nickel (Ni), Carbon (C), or an alloy thereof, such as a Copper alloy or Copper-Nickel alloy.

The first layer may have a thickness of about 5-150 μm, 5-100 μm, 5-75 μm, 5-40 μm, 9-30 μm or 10-20 μm.

According to one embodiment, the first layer may have a thickness of of more than 40 μm, preferably 40-150 μm or 40-100 μm, more preferably 40-90 μm, 50-80 μm or 60-70 μm.

The first layer may have a machinability value, measured as specific cutting force (K_{c1}), of more than 300 N/mm², preferably more than 500 N/mm², more preferably more than 700 N/mm².

The specific cutting force is the force, in the cutting direction, needed to cut a chip area of 1 mm² that has a thickness of 1 mm.

The first layer may have a machinability value, measured as specific cutting force (k_{c1}) of 300-1800 N/mm², preferably about 300-400 N/mm², about 400-500 N/mm², about 500-600 N/mm², about 600-700 N/mm², about 700-800 N/mm², about 800-900 N/mm², about 900-1000 N/mm², about 1000-1100 N/mm², about 1100-1200 N/mm², about 1200-1300 N/mm², about 1300-1400 N/mm², about 1400-1500 N/mm², about 1500-1600 N/mm², about 1600-1700 N/mm², or about 1700-1800 N/mm².

The second layer may be formed of a dielectric material.

For example, the second layer may be formed of a plastic material or paper.

The second layer may be formed of Polyethylene terephthalate (PET), Polycarbonate (PC), Polyimide (PI), Polyethylene naphtalate (PEN) or paper.

The second layer may have a thickness of about 20-200 μm, 20-150 μm or 20-100 μm, preferably 20-90 μm or 30-80 μm, more preferably 35-75 μm or 45-65 μm.

The multilayer material may comprise a cover layer covering at least a portion of a first surface of the first layer.

The first surface can be seen to form a top surface of the first layer. The first surface of the first layer is opposite to a second surface of the first layer. The second surface can be seen to face the second layer or another underlying layer of the multilayer material.

At least a portion of material may be removed from the cover layer when the multilayer material is passed though the first nip.

The cover layer may be formed of a dielectric material.

The multilayer material may comprises at least one additional conductive layer.

The at least one additional conductive layer may be formed of one or several metals, a metal alloy or a polymer.

The at least one additional conductive layer may be formed of Aluminum (Al), Copper (Cu), Copper Cladded Aluminum (CCA), Tin (Sn), Gold (Au), Silver (Ag), Nickel (Ni), Carbon (C), or an alloy thereof, such as a Copper alloy or Copper-Nickel alloy.

The at least one additional conductive layer may be formed of the same material as the first layer, or a different material.

The at least one additional conductive layer may have substantially the same thickness as the first layer, or a different thickness. The additional conductive layer may have a smaller thickness than the first layer. Alternatively, the additional conductive layer may have a greater thickness than the first layer.

The at least one additional conductive layer may be provided as an intermediate conducitve layer sandwhiched between the second layer and an intermediate dielectric layer.

In such case, the first layer can be seen to be arranged on top of the intermediate dielectric layer.

Alternatively, the second layer may be provided between the first layer and the additional conductive layer.

The method may further comprise removing material from said at least one additional conductive layer.

The milling cutter may have a cylindrical shape and has teeth extending on its envelope along a length direction of the cylinder.

The patterned cliché cylinder may have a surface relief pattern on its envelope.

According to a second aspect, there is provided a device for producing a product comprising a substrate with at least one 2D-patterned layer from a multilayer material. Thee device comprises: at least one milling cutter configured to cooperate with at least one patterned cliché cylinder to form a nip, for selectively removing predetermined portions of material from a first layer of the multilayer material in accordance with a pattern of the patterned cliché cylinder, so as to form the 2D-patterned layer from the first layer. The device is configured such that it, in use, provides a first such nip for removing partially, as seen in a thickness direction of the first layer, at least some of the predetermined portions of material from the first layer. The device is configured such that it, in use, provides a second such nip for removing a remainder of said at least some of the predetermined portions of material.

The device is configured such that, when in use, the multilayer material can be forced against an envelope surface of the patterned cliché cylinder of the first nip by applying a tensile stress on the running material, such that a first pattern is formed in the multilayer material. Thereby, elevated portions can be seen to be formed in the multilayer material. A milling cutter of the first nip is adapted to simultenously remove material from the elevated portions of the multilayer material.

The device is configured such that, when in use, the multilayer material can be forced against an envelope surface of the patterned cliché cylinder of the second nip by applying a tensile stress on the running material, such that a second pattern is formed in the multilayer material. Thereby, elevated portions can be seen to be formed in the multilayer material. A milling cutter of the second nip is adapted to simultenously remove material from the elevated portions of the multilayer material.

The first pattern and the second pattern formed in the multilayer material may be the same or different patterns. Thus, the first pattern and the second pattern formed in the multilayer material may have the same dimensions or different dimensions.

Thus, a first cliché cylinder of the first nip and a second cliché cylinder of the second nip may present patterns with the same dimensions, or with different dimensions.

The device may be used in a method as described above.

According to some embodiments, the first nip may be formed by a first patterned cliché cylinder and a first milling cutter, and the second nip may be formed by the first patterned cliché cylinder and a second milling cutter.

Thus, one and the same cliché cylinder may be arranged such that it forms part of different nips. Thereby, one and the same cliché cylinder may be used for a plurality of milling steps.

Consequently, the first and second nips may be formed by the same patterned cliché cylinder, but separate milling cutters.

Thus, the first nip and second nip may be seen to be arranged adjacent one another.

The first milling cutter and the second milling cutter may be arranged in the same fixture.

Thus, the first and second milling cutters may be seen to be arranged adjacent one another.

The first and second milling cutters may be configured to operate at the same or different speed. The first and second milling cutters may be configured to operate with the same or different rotational direction.

Such device allows for cost-savings and efficient method of producing a product comprising a substrate with at least one patterned layer.

A first position of the first milling cutter and a second position of the second milling cutter may be adjustable relative one another.

Thus, the relative position of the first and second milling cutters in the same fixture may be adjustable. For example, the milling cutters may be adjustable relative one another such that an offset can be achieved between the first and second milling cutters. By being adjustable, the first and second milling cutters may be configured to operate with different cutting depths as compared with one another.

As an alternative of being arranged in the same fixture, the first milling cutter and the second milling cutter may be arranged in separate fixtures.

Consequently, the first and second milling cutters may be seen to be arranged independently of one another. Thus, the first and second milling cutter may be seen to be arranged spaced apart.

The first and second milling cutters may be configured to operate at the same or different speed. The first and second milling cutters may be configured to operate with the same or different rotational direction.

According to one embodiment, the first nip may be formed by a first milling cutter and a first patterned cliché cylinder, and the second nip may be formed by a second milling cutter and a second patterned cliché cylinder.

Thus, the first nip and the second nip may be seen to be arranged spaced apart.

According to another embodiment, the first nip may be formed by a first milling cutter and a first patterned cliché cylinder, and the second nip may be formed by the first milling cutter and a second patterned cliché cylinder.

Thus, one and the same milling cutter may be arranged such that it forms part of different nips. Thereby, one and the same milling cutter may be used for a plurality of milling steps.

Consequently, the first and second nips may be formed by the same milling cutter but separate patterned cliché cylinders.

Thus, the first nip and second nip may be seen to be arranged adjacent one another.

A first pattern of the first patterned cliché cylinder may have the same dimensions as a second pattern of the second patterned cliché cylinder.

Alternatively, a first pattern of the first patterned cliché cylinder may have different dimensions as compared to a second pattern of the second patterned cliché cylinder.

The method and device according to the above can be used to produce a product comprising a substrate with at least one patterned layer. The product may be seen to form an electronic component. Such electronic component may be used to produce heaters, heating elements, flexible circuit boards, LED lighting, cable bundles etc.

### BRIEF DESCRIPTION OF THE DRAWINGS

Embodiments of the present solution will now be described, by way of example, with reference to the accompanying schematic drawings in which:

FIG. 1a schematically illustrates a patterned multilayer material comprising a first layer and a second layer.

FIG. 1b schematically illustrates a patterned multilayer material comprising a cover layer, a first layer, and a second layer.

FIG. 1c schematically illustrates a patterned multilayer material comprising a first layer, an intermediate dielectric layer, a conductive layer, and a second layer.

FIG. 1d schematically illustrates a patterned multilayer material comprising a first layer, a second layer and a conductive layer.

FIG. 1e schematically illustrates one embodiment of a first layer of the multilayer material.

FIG. 1f schematically illustrates another embodiment of a first layer of the multilayer material.

FIGS. 2a schematically illustrates a method comprising two milling steps.

FIGS. 2b schematically illustrates a method comprising three milling steps.

FIGS. 3a-3d schematically illustrate different embodiments of a method comprising two milling steps and different embodiments of cliché patterns.

FIGS. 4a schematically illustrates an embodiment of a device comprising one patterned cliché cylinder and one milling cutter.

FIGS. 4b-4e schematically illustrate different embodiments of a device comprising at least one patterned cliché cylinder and at least one milling cutter.

FIG. 5 illustrates one embodiment of a milling cutter and a patterned cliché cylinder, and a patterned multilayer material.

FIG. 6 illustrates a cliché cylinder.

### DESCRIPTION OF EMBODIMENTS

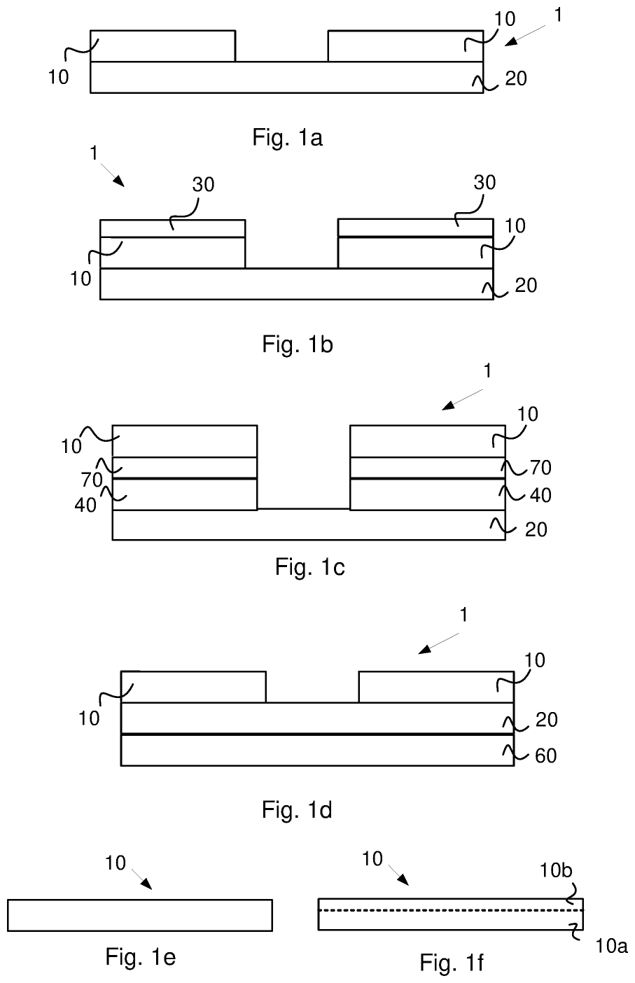

In relation to FIGS. 1-6, a method for producing a product comprising a substrate with at least one patterned layer will be described.

The method comprises providing a multilayer material 1 comprising at least a first layer 10 and a second layer 20.

FIGS. 1a-1d illustrate different embodiments of a multilayer material 1 that has been provided with a pattern in accordance with the method. As illustrated, the multilayer material 1 can comprise a plurality of layers 10, 20, 30, 40, 60, 70.

As illustrated in FIGS. 1a-1d, the multilayer material 1 comprises at least a first layer 10 and a second layer 20.

The multilayer material 1 is a flexible material. For example, the multilayer material 1 may be provided in form of a foil or a film.

The flexible material may be provided in form of a continious web or in form of a sheet. Thus, the multilayer material may be provided from a material supply 100 such as a web unwinding roll (not illustrated) or a supply holding a plurality of sheets (not illustrated).

The second layer 20 of the multilayer material 1 may be seen to form a substrate layer or a bottom carrier layer. The second layer 20 may be formed of a dielectric material. For example, the second layer may be formed of a plastic material or paper. The second layer may be formed of Polyethylene terephthalate (PET), Polycarbonate (PC), Polyimide (PI), Polyethylene naphtalate (PEN) or paper. The second layer may have a thickness of about 20-200 μm, 20-150 μm or 20-100 μm, preferably 20-90 μm or 30-80 μm, more preferably 35-75 μm or 45-65 μm.

As illustrated in FIGS. 1a, 1c and 1d, the first layer 10 of the multilayer material 1 may be seen to form a top layer that is to be provided with a structure or pattern. Alternatively, the first layer 10 may be seen to form an intermediate layer, such as for example a layer formed between the second layer 20 and a cover layer 30 as illustrated in FIG. 1b.

The first layer 10 may be formed of a conductive material. The first layer 10 may be formed of one or several metals, a metal alloy or a polymer. The first layer 10 may for example be formed of Aluminum (Al), Copper (Cu), Copper Cladded Aluminum (CCA), Tin (Sn), Gold (Au), Silver (Ag), Nickel (Ni), Carbon (C), or an alloy thereof, such as a Copper alloy or Copper-Nickel alloy.

As illustrated in FIG. 1e, the first layer 10 may be formed of one metal, metall alloy or a polymer. As illustrated in FIG. 1f, the first layer may be formed of at least two different metals, for example two different metals presenting different characteristics. Thus, as illustrated in FIG. 1f, the first layer 10 may be seen to comprise at least a first sublayer 10a of a first metal and a second sublayer 10b of a second metal. The first and second sublayers 10a, 10b may present the same or different thicknesses. For example, in the case of the first layer 10 being formed of CCA, the first sublayer 10a can be seen to be formed of Aluminium (Al) and the second sublayer 10b can be seen to be formed of Copper (Cu). In such case, the first sublayer 10a is preferably thicker than the second sublayer 10b.

The first layer 10 may have a thickness of about 5-150 μm, 5-100 μm, 5-75 μm, 5-40 μm, 9-30 μm or 10-20 μm. According to some embodiments, the first layer 10 may have a thickness of of more than 40 μm, preferably 40-150 μm or 40-100 μm, more preferably 40-90 μm, 50-80 μm or 60-70 μm.

As one example, the first layer 10 may be an aluminium layer having a thickness of more than 40 μm. As another example, the first layer 10 may be a copper layer having a thickness of more than 10 μm.

The first layer may be seen to be formed of a material that presents difficulties in machinability. The first layer 10 may have a machinability value, measured as specific cutting force k_{c1}, of more than 300 N/mm², preferably more than 500 N/mm², more preferably more than 700 N/mm².

In some embodiments, the first layer 10 has a machinability value, measured as specific cutting force (k_{c1}) of 300-1800 N/mm², preferably about 300-400 N/mm², about 400-500 N/mm², about 500-600 N/mm², about 600-700 N/mm², about 700-800 N/mm², about 800-900 N/mm², about 900-1000 N/mm², about 1000-1100 N/mm², about 1100-1200 N/mm², about 1200-1300 N/mm², about 1300-1400 N/mm², about 1400-1500 N/mm², about 1500-1600 N/mm², about 1600-1700 N/mm², or about 1700-1800 N/mm².

As illustrated in FIG. 1b, the multilayer material 1 may further comprise at least one cover layer 30 covering at least a portion of a first surface of the first layer 10. The first surface can be seen to form a top surface of the first layer 10. The first surface of the first layer 10 is opposite to a second surface of the first layer. The second surface can be seen to face the second layer 20 of the multilayer material 1, or another underlying layer. The at least one cover layer 30 may be formed of a dielectric material. The thickness of the cover layer 30 is preferably smaller than the thickness of the first layer 10.

As one example, the multilayer material 1 may comprise a second layer 20 in form of a substrate, a first layer 10 formed of a conductive material, and a cover layer 30.

The multilayer material 1 may further comprise at least one additional conductive layer 40, 60. The at least one additional conductive layer 40, 60 may be formed of one or several metals, a metal alloy or a polymer. The at least one additional conductive layer 40, 60 may be formed of Aluminum (Al), Copper (Cu), Copper Cladded Aluminum (CCA), Tin (Sn), Gold (Au), Silver (Ag), Nickel (Ni), Carbon (C), or an alloy thereof, such as a Copper alloy or Copper-Nickel alloy. The at least one additional conductive layer 40, 60 may be formed of the same material as the first layer 10, or a different material.

The at least one additional conductive layer 40, 60 may have substantially the same thickness as the first layer 10, or a different thickness. The additional conductive layer 40, 60 may have a smaller thickness than the first layer 10. Alternatively, the additional conductive layer 40, 60 may have a greater thickness than the first layer 10.

As illustrated in FIG. 1c, the multilayer material 1 may comprise an intermediate conductive layer arranged between the first layer 10 and the second layer 20. The multilayer material 1 may further comprise an intermediate dielectic layer 70. Thus, as illustrated in FIG. 1c, the at least one additional conductive layer 40 may provided as an intermediate conducitve layer sandwhiched between the second layer 20 and the intermediate dielectric layer 70.

As one example, the multilayer material 1 may comprise a second layer 20 in form of a substrate forming a bottom layer, a first layer 10 formed of a conductive material forming a top layer, an additional conductive layer 40, and an intermediate dielectric layer 70 formed between the first layer 10 and the additional conductive layer 40.

As illustrated in FIG. 1d, the multilayer material 1 may comprise an additional conductive layer 60. As illustrated, the conductive layer 60 may be arranged on an opposite side of the second layer 20, as compared with the first layer 10. Thus, the second layer 20 can be seen to be arranged between the first layer 10 and the additional conductive layer 60. The first layer 10 and the conductive layer 60, may present identical layers or different layers. Thus, the first layer 10 and the conductive layer 60 may be formed of the same material and/or have the same thickness.

As one example, the multilayer material 1 may comprise a second layer 20 in form of a substrate, a first layer 10 formed of a conductive material, and an additional conductive layer 60, wherein the first layer 10 and the conducitve layer 60 is arranged on opposite sides of the substrate.

Further, although not illustrated, the multilayer material 1 may comprise at least one adhesive layer. An adhesive may be provided between each layer, or between at least two adjacent layers. For example, at least one adhesive layer may be provided between the first and second layers 10, 20. Alternatively, or additionally, at least one adhesive layer may be provided between the first layer 10 and the cover layer 30. Alternatively, or additionally, at least one adhesive layer may be provided between the first layer 10 and the intermediate dielectric layer 70. Alternatively, or additionally, at least one adhesive layer may be provided between the intermediate dielectric layer 70 and the additional conductive layer 40. Alternatively, or additionally, at least one adhesive layer may be provided between the second layer 20 and the additional conductive layer 40. Alternatively, or additionally, at least one adhesive layer may be provided between the second layer 20 and the additional conductive layer 60.

Although not illustrated, it is understood that other multilayer materials than the ones illustrated in FIGS. 1a-1d is possible. For example, the multilayer material 1 as illustrated in FIGS. 1c and 1d may further comprise a cover layer. Further, a multilayer material as illustrated in FIG. 1c may be provided with additional conductive layers and/or dielectric layers.

Further, the method comprises providing at least one nip 6, 6a, 6b formed by a patterned cliché cylinder 52, 52a, 52b and a cooperating milling cutter 51, 51a, 51b.

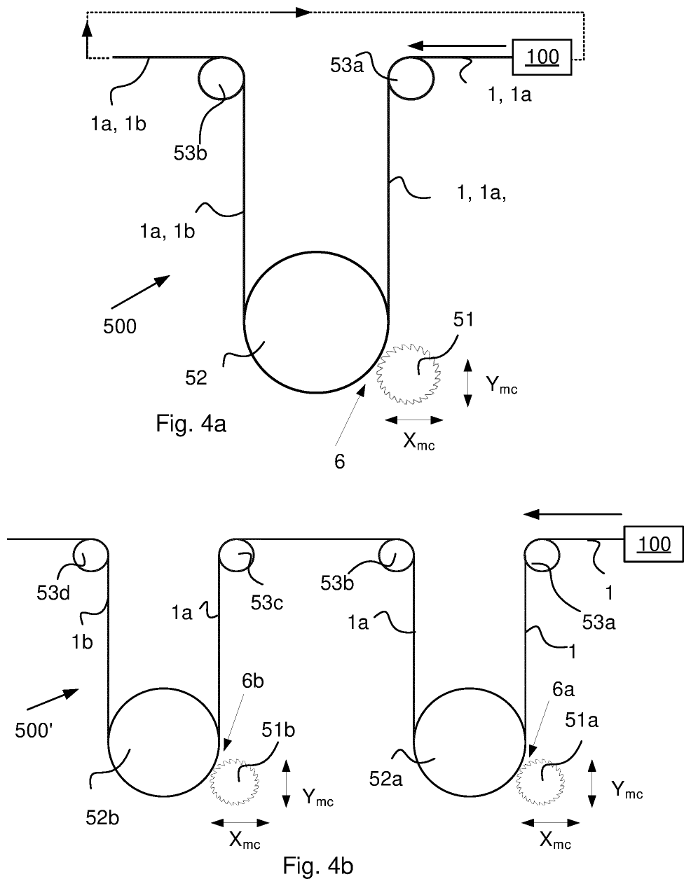

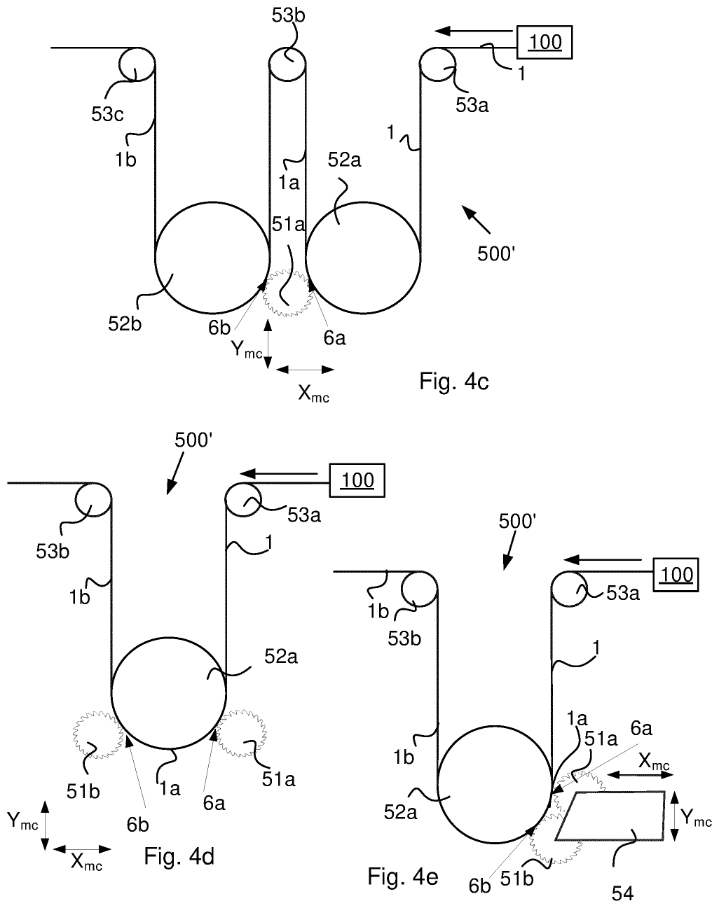

According to one embodiment, a nip 6 may be formed by a patterned cliché cylinder 52 and a milling cutter 51. The multilayer material 1 may be passed by said nip 6 at least two times, see for example FIG. 4a. Thus, said nip 6 can be seen to form both a first nip and a second nip.

Thus, one and the same milling cutter 51 and patterned cliché cylinder 52 may be used for a plurality of milling steps. The multilayer material may be passed by the same milling cutter 51 and cliché cylinder 52 at least two times, wherein a milling step is performed each time.

A first material feed rate of the first milling step may be the same or may differ from a second material feed rate of the subsequent milling step.

A first milling cutter speed of the first milling step may be the same or may differ from a second milling cutter speed of the subsequent milling step.

According to another embodiment, a first nip 6a may be formed by a first patterned cliché cylinder 52a and a first milling cutter 51a. A second nip 6b may be formed by a second patterned cliché cylinder 52b and a second milling cutter 51b, see for example FIG. 4b.

According to yet another embodiment, a first nip 6a may be formed by a first patterned cliché cylinder 52a and a first milling cutter 51a. A second nip 6b may be formed by a second patterned cliché cylinder 52b and the first milling cutter 51a, see for example FIG. 4c.

According to yet another embodiment, a first nip 6a may be formed by a first patterned cliché cylinder 52a and a first milling cutter 51a. A second nip 6b may be formed by the first patterned cliché cylinder 52a and a second milling cutter 51b, see for example FIGS. 4d-4e. The first and second milling cutters 51a, 51b may be set to operate with the same or different milling cutter speed. Thus, a first milling cutter speed of the first milling step may be the same or different as a second milling cutter speed in the subsequent milling step. Further, the first and second milling cutters 51a, 51b may be set to operate with the same or different rotational direction. Thus, a first milling cutter rotational direction may be the same or different as a second milling cutter rotational direction in the subsequent milling step.

As illustrated in FIGS. 4b-4e, in the first milling step, the multilayer material 1 may be passed through said first nip 6a. In the subsequent milling step, the multilayer material 1a may be passed through the second nip 6b.

Thus, as an alternative of providing one patterned cliché cylinder 52 and one milling cutter 51, as illustrated in FIG. 4a, a plurality of patterned cliché cylinders 52a, 52b and/or a plurality of milling cutters 51a, 51b may be provided, as illustrated in FIGS. 4b-4e.

Further, the method comprises passing the multilayer material 1 through at least one nip 6, 6a, 6b to remove predetermined portions of material from the first layer 10. I.e. the method comprises passing the multilayer material 1 through at least one nip 6, 6a, 6b such that the milling cutter 51, 51a, 51b removes predetermined portions of material from the first layer 10 in accordance with a pattern of the patterned cliché cylinder 52, 52a, 52b, whereby the patterned layer is formed on the multilayer material 1.

The removal of at least some of the predetermined portions of material from the first layer 10 is performed partially, as seen in a thickness direction of the first layer, in at least one first milling step. A remainder of said at least some of the predetermined portions of material is removed in a subsequent milling step.

Consequently, the removal of material from the first layer 10 is performed partially in one or several first milling steps and is completed in a subsequent final milling step. Thus, the material that is to be removed from the first layer 10 can be removed in two or more milling steps. After the final milling step, at least the first layer 10 has been cut through and predetermined portions of material have been removed from the first layer 10, such that at least a portion of an adjacent, underlying layer of the multilayer material 1 is exposed. Thus, a pattern can be seen to be formed in at least the first layer 10 of the multilayer material.

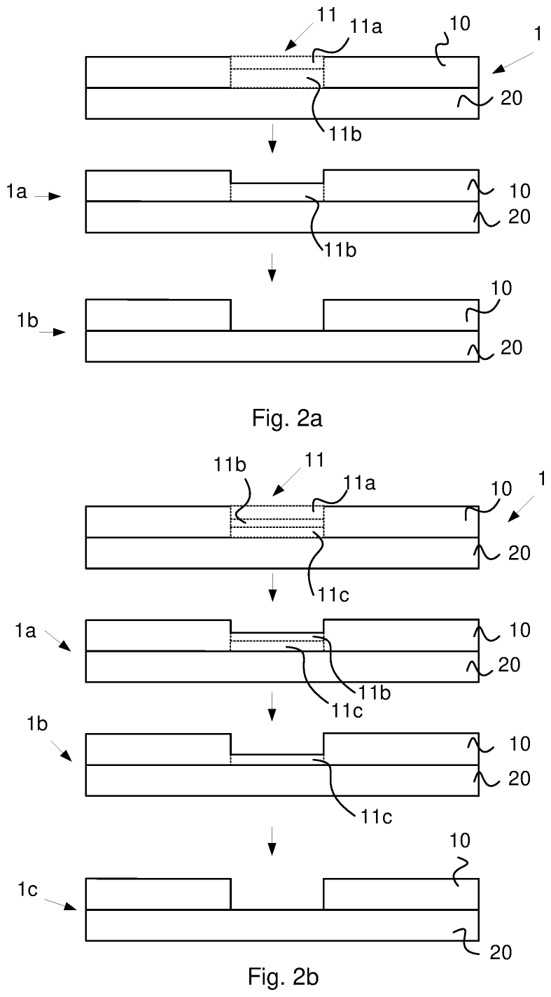

According to one embodiment, the method comprises two milling steps, see for example FIG. 2a. FIG. 2a illustrates a method comprising a first milling step, and a subsequent second milling step. FIG. 2a illustrates one predetermined portion of material 11 that is to be removed from the first layer of the multilayer material 1. In a first milling step, the predetermined portion of material 11 is partially removed, as seen in the thickness direction, from the multilayer material 1. Thereby, a multilayer material 1a with an 10 incomplete pattern is provided. In the subsequent, second milling step, the remaining material of the predetermined portion of material 11 is removed from the multilayer material 1a. Thereby, a clearly defined pattern, preferably with sharp edges, is provided in the first layer 10 of the multilayer material. Thus, a multilayer material 1b comprising at least one patterned layer is provided.

Consequently, the method may comprise in a first milling step, removing a first part 11a of a predetermined portion of material 11 that is to be removed from the first layer 10. In the first milling step, 1-90% of said predetermined portion of material 11 may be removed, preferably 5-85%, 15-80% or 25-75%, more preferably 30-70% or 40-60%. Thus, the first part of material 11a removed in the first milling step can be seen to correspond to 1-90%, preferably 5-85%, 15-80% or 25-75%, more preferably 30-70% or 40-60%, of said predetermined portion of material 11 that are to be removed from the first layer. Further, the method may comprise, in the subsequent milling step, removing a second part 11b of the predetermined portion of material 11. As illustrated in FIG. 2a, the second part 11b may correspond to the remaining material of the predetermined portion of material 11 that is to be removed from the first layer 10.

According to another embodiment, the method comprises three milling steps, see for example FIG. 2b. FIG. 2b illustrates a method comprising two first milling steps, and a subsequent third milling step. FIG. 2b illustrates one predetermined portion of material 11 that is to be removed from the first layer 10 of the multilayer material 1. In a first milling step, the predetermined portion of material 11 is partially removed, as seen in the thickness direction, from the multilayer material 1. Thereby, a multilayer material 1a with an incomplete pattern is provided. In a second milling step, the predetermined portion of material 11 is partially removed, as seen in the thickness direction, from the multilayer material 1a. Thereby, a multilayer material 1b with an incomplete pattern is provided. In a subseqent, third milling step, the remaining material of the predetermined portion of material 11 is removed from the multilayer material 1b. Thereby, a clearly defined pattern is provided in the first layer 10 of the multilayer material. Thereby, a multilayer material 1c comprising at least one patterned layer is provided.

Consequently, the method may comprise in a first milling step, removing a first part 11a of a predetermined portion of material 11 that is to be removed from the first layer 10. The method may further comprise, in a second milling step, removing a second part 11b of said predetermined portion of material 11. Further, the method may comprise, in a subsequent, third milling step, removing a third part 11c of the predetermined portion of material 11. As illustrated in FIG. 2b, the third portion 11c may correspond to the remaining material of the predetermined portion of material 11 that is to be removed from the first layer 10.

Although not illustrated, it is understood that more than three milling steps can be used to remove the predetermined portions of material from the first layer 10.

Further, although FIG. 2a-2b illustrates removing material from a multilayer material comprising two layers 10, 20, it is understood that other multilayers material may be used in the method, such as for example the ones described in relation to FIGS. 1a-1f.

Further, the method may comprise removing material from at least one additional layer of the multilayer material 1. Thus, the method may comprise removing material from the first layer 10 and at least one other layer of the multilayer material 1. For example, the method may comprise removing at least a portion of material from a cover layer 30, see FIG. 1b. Material may be removed from the cover layer 30 in the at least one first milling step. Preferably, material is removed from the cover layer 30 along with a portion of the first layer 10 in the at least one first milling step.

As another example, material may be removed from an intermediate dielectric layer 70 and optionally also an additional conductive layer 40, as illustrated in FIG. 1c. As another example, material may be removed from at least one adhesive layer (not illustrated).

Although not illustrated in FIG. 1d, material may be removed from the second layer 20.

At least one layer of the multilayer material is not cut through, i.e. the whole multilayer material 1 is not cut through. Preferably, at least one layer of the multilayer material 1 remains untouched, or only partly machined. For example, a second layer 20 forming a substrate layer may remain untouched. Thus, a maximum cutting depth is smaller than the thickness of the multilayer material 1.

The method may comprise, in the at least one first milling step, partially removing the predetermined portions of material evenly, as seen in the thickness direction, over the entire substrate.

Alternatively, the method may comprise, in the at least one first milling step, removing parts of the predetermined portions of material entirely, as seen in the thickness direction, while other parts of the predetermined portions of material are only removed partially, as seen in the thickness direction.

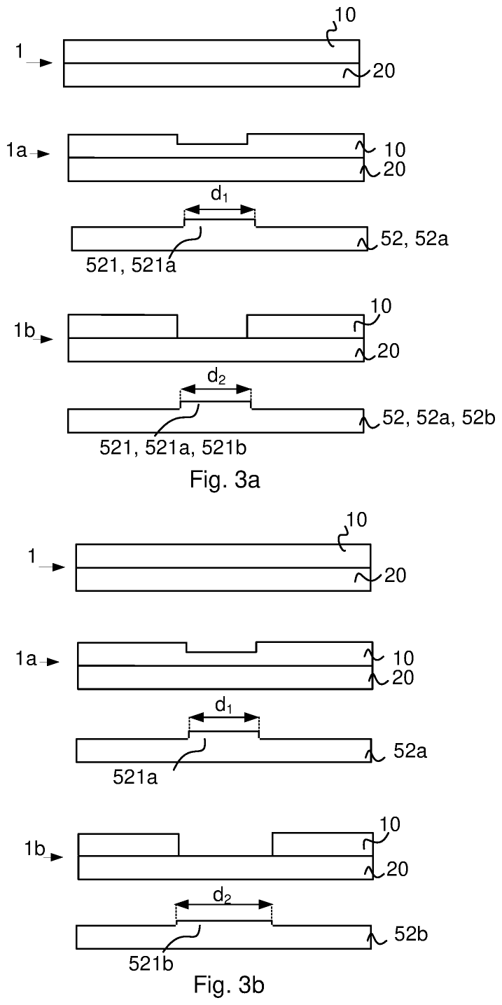

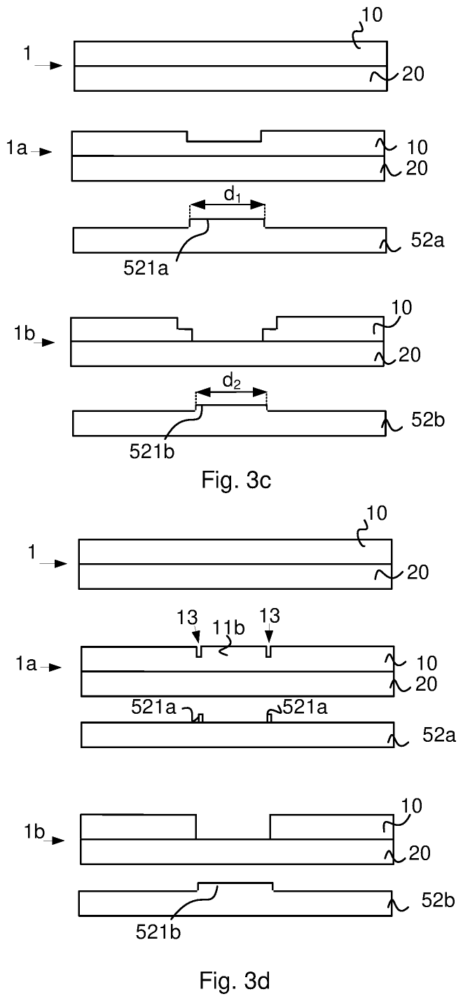

As illustrated in FIGS. 3a-3d, the cutting dimensions may be the same or different in the at least one first milling step and the subsequent milling step.

In the first milling step, the milling cutter 51, 51a may be set to operate with a first cutting depth. In the subsequent milling step, the milling cutter 51, 51a, 51b may be set to operate with a second cutting depth. The second cutting depth may be larger than the first cutting depth.

The distance between the patterned cliché cylinder 52, 52a, 52b and the milling cutter 51, 51a, 51b, determines the cutting depth. In the final milling step, said distance may be adjusted in order to ensure that a clear pattern is formed on the multilayer material 1. Preferably, the edges of the formed pattern shall be sharp.

The cutting depth can be monitored by one or several measuring methods. The cutting depth may be directly and/or indirectly monitored. For example, the cutting depth may be monitored by measuring a tool gap and/or by measuring on the produced product. Methods for monitoring the cutting depth is known in the art, and will not be described further.

Further, the patterned cliché cylinder 52, 52a used in the first milling step may present a first pattern dimension d₁. The patterned cliché cylinder 52, 52a, 52b used in the subsequent milling step may present a second pattern dimension d₂.

As illustrated in FIG. 3a, the first pattern dimension d₁ may be the same as the second pattern diameter d₂. Alternatively, as illustrated in FIG. 3b, the first pattern dimension d₁ may be smaller than the second pattern dimension d₂. As yet another alternative, as illustrated in FIG. 3c, the first pattern dimension di may be larger than the second pattern dimension d₂.

As illustrated in FIG. 3d, the at least one first milling step may comprise forming at least one groove 13 in the first layer 10. Thus, after the at least one first milling step, at least one groove 13 can be seen to be formed in the first layer 10. The at least one groove 13 may have a depth corresponding to the thickness of the first layer 10, or a depth being smaller than the thickness of the first layer 10. The at least one groove 13 can be seen to frame or circumferent a remaining portion of material that is to be removed in the subsequent milling step.

Thus, in the at least one first milling step, only one or several edge parts of at least some of the predetermined portions of material that are to be removed, may be removed from the first layer 10, while the remaining part of material 11b is removed in the subsequent milling step. The edge parts can be seen to form a frame or perimeter of said at least some of the predetermined portions of material that are to be removed.

Consequently, as is illustrated in FIGS. 3a-3d, the method may comprise providing patterned cliché cylinders 52, 52a, 52b with the same or different patterns. For example, a first pattern 521a of a first patterned cliché cylinder 52a used in a first milling step may present the same dimensions as a second pattern 521b of a second patterned cliché cylinder 52b used in a subsequent milling step, see for example FIG. 3a. Alternatively, a first pattern 521a of a first patterned cliché cylinder 52a used in a first milling step may present different dimensions as compared to a second pattern 521b of a second patterned cliché cylinder 52b used in a subsequent milling step, see for example FIGS. 3b-3d.

It is understood that the method may comprise more than two milling steps. Although FIGS. 4a-4e illustrate passing the multilayer material through one nip 6 two times (FIG. 4a) or through two nips 6a, 6b (FIGS. 4b-4e) it is understood that the material may be passed by said one nip 6 more than two times or passed by additional nips (not illustrated).

After the final milling step of the method the multilayer material has been provided with the desired pattern. The multilayer material may then be fed out of the device. The material may be fed out of the device to a material supply (not illustrated). For example, in the case of the multilayer material being a continous web, the patterned multilayer material may be rolled onto a material winding roll (not illustrated). As another example, when the multilayer material is provided in form of a sheet, the sheet may be fed to a sheet supply (not illustrated).

A device 500, 500′ as illustrated in any one of FIGS. 4a-4e may be used in a method as described above.

In relation to FIGS. 4-6, different embodiments of a device for producing a product comprising a substrate with at least one patterned layer will now be described.

As illustrated in FIGS. 4a-4e, the device is configured to provide at least one nip 6, 6a, 6b. The nip 6, 6a, 6b is formed by a patterned cliché cylinder 52, 52a, 52b and a cooperating milling cutter 51, 51a, 51b.

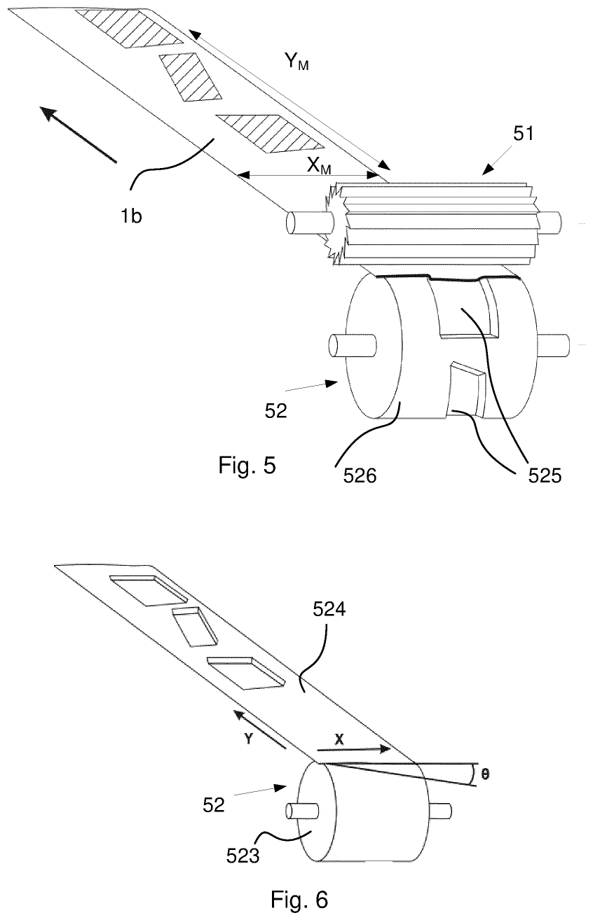

The at least one milling cutter 51, 51a, 51b of the device 500, 500′ can be provided in form of a milling cylinder. The milling cutter may be provided in form of a cylindrical milling wheel, with cutting teeth running along an axial direction of an envelope surface of the cylinder, such as helically or straight along the axial direction. FIG. 5 illustrates one example of a milling cylinder 51. However, it is understood that other embodiments are possible.

As illustrated in FIGS. 4b, 4d and 4e, the device 500′ may comprise multiple milling cutters 51a, 51b. The multiple mililing cutters may be designed identically, substantially the same or differently. For example a diameter of said multiple milling cylinders 51a, 51b may be the same or different. As another example, the size and/or number of teeth of the milling cylinders 51a, 51b may be the same or different.

The at least one patterned cliché cylinder 52, 52a, 52b of the device 500, 500′ can be provided in the form of a cylindrical carrier with a patterned envelope surface. The pattern comprises raised portions 526 and recessed portions 525 which make up the pattern. The raised portions 526 correspond to portions of material that are to be cut away from the multilayer material 1. The recessed portions 525 correspond to portions of material that are to be kept. The patterned cliché cylinder 52, 52a, 52b may be formed as a metal plate 524, which may be made from a magnetic material (e. g. steel) so that it can be magnetically attached to a magnetic carrying cylinder 523. Patterned cliché cylinders and the manufacturing of such are known in the art, see for example EP16665912B1, and will not be described further. FIG. 5 illustrates one example of a patterned cliché cylinder 52. However, it is understood that other embodiments are possible.

As illustrated in FIGS. 4b and 4c, the device 500′ may comprise multiple patterned cliché cylinders 52a, 52b. The muliple patterned cliché cylinders 52a, 52b may be designed identically, substantially the same or differently. For example, the patterned cliché cylinders 52a, 52b may present patterns with the same or different dimensions. As one example, a first patterned cliché cylinder 52a may present a first pattern dimension d₁ and the second patterned cliché cylinder 52b may presents a second pattern dimension d₂. The first pattern dimension d₁ may be the same as the second pattern dimension d₂. Alternatively, the first pattern dimension d₁ may be larger than the second pattern dimension d₂. Alternatively, the first pattern dimension d₁ may be smaller than the second pattern dimension d₂.

The patterned cliché cylinder 52, 52a, 52b may be mounted in fixed bearings on a stand while the milling cutter 51, 51a, 51b may be movably arranged in a direction to or from the patterned cliché cylinder 52, 52a, 52b in order to widen or shorten said nip 6, 6a, 6b. Alternatively, the cliché cylinder 52, 52a, 52b may be movable relative the milling cutter 51, 51a, 51b. Alternatively, both the cliché cylinder 52, 52a, 52b, and the milling cutter 51, 51a, 51b may be movable relative one another.

Thus, when in use, the multilayer material 1 can be forced against an envelope surface of the cliché cylinder 52, 52a, 52b, by applying a tensile stress on the running material. Thereby, at least the first layer 10 of the multilayer material can be shaped into a three-dimensional pattern of ridges and valleys. Thereby, elevated portions can be seen to be formed in the multilayer material 1. The cooperating milling cutter 51, 51a, 51b is adapted to simultenously remove material from the elevated portions of the multilayer material 1.

As illustrated in FIG. 4a, the device 500 may comprise one nip 6 formed by a milling cylinder 51 and a patterned cliché cylinder 52.

As illustrated in FIGS. 4b-4e, the device 500′ may comprise a first nip 6a formed by a patterned cliché cylinder 52a and a cooperating milling cutter 51a. The device 500′ may further comprise a second nip 6b formed by a patterned cliché cylinder 52a, 52b and a cooperating milling cutter 51a, 51b.

As illustrated in FIG. 4b, the first nip 6a may be formed by a first milling cutter 51a and a first patterned cliché cylinder 52a. The second nip 6b may be formed by a second milling cutter 51b and the second patterned cliché cylinder 52b. Thus, the first nip 6a and the second nip 6b may be seen to be arranged spaced apart.

As illustrated in FIG. 4c, the first nip 6a may be formed by a first milling cutter 51a and a first patterned cliché cylinder 52a. The second nip 6b may be formed by the first milling cutter 51a and a second patterned cliché cylinder 52b. Consequently, the first and second nips 6a, 6b may be formed by the same milling cutter 51a, but separate patterned cliché cylinders 52a, 52b. The first milling cutter 51a, may be movable in an Y_{mc}-direction and/or X_{mc}-direction, as illustrated in FIG. 4c.

As illustrated in FIGS. 4d-4e, the first nip 6a may be formed by a first patterned cliché cylinder 52a and a first milling cutter 51a. The second nip 6b may be formed by the first patterned cliché cylinder 52a and a second milling cutter 51b. Consequently, the first and second nips 6a, 6b may be formed by the same patterned cliché cylinder 52a, but separate milling cutters 51a, 51b.

As illustrated in FIG. 4d, the first milling cutter 51a and the second milling cutter 51b may be arranged seperately. For example, the first and second milling cutters 51a, 51b may be arranged in separate fixtures (not illustrated). Thus, the first and second milling cutters 51a, 51b may be seen to be arranged independently of one another. The milling cutters 51a, 51b may be movable in an Y_{mc}-direction and/or X_{mc}-direction, independently of one another, as illustrated in FIG. 4d.

As illustrated in FIG. 4e, the first milling cutter 51a and the second milling cutter 51b may be arranged in the same fixture 54. Thus, the first and second milling cutters 51a, 51b may be seen to be arranged adjacent one another. The fixture 54 may be movable in an Y_{mc}-direction and/or X_{mc}-direction, as illustrated in FIG. 4e. Thus, the milling cutters 51a, 51b may be movable simultenously, in an Y_{mc}-direction and/or X_{mc}-direction.

The first milling cutter 51a and second milling cutter 51b may be adjustable relative one another in the fixture 54. For example, the milling cutters 51a, 51b may be adjustable relative one another such that an offset can be achieved between the first and second milling cutters 51a, 51b. By being adjustable relative one another, the first and second milling cutters 51a, 51b may be configured to operate with different cutting depths as compared with one another. Consequently, when in use, the relative position of the milling cutters 51a, 51b can be adjusted so that the cutting depth of each milling cutter 51a, 51b can be controlled. The relative position of the milling cutters 51a, 51b can be adjusted so that the cutting depth of the first milling step and the subsequent milling step are optimized for a clearly defined pattern. Preferably, when in use, the relative positions of the milling cutters 51a, 51b are fixed during the milling operations.

Further, the first and second milling cutters 51a, 51b as illustrated in FIG. 4d and FIG. 4e may be configured to operate at the same or different speed. Further, the first and second milling cutters 51a, 51b may be configured to operate with the same or different rotational direction.

Although not illustrated, the device 500′ may comprise further milling cutters and/or patterned cliché cylinders. Thus, although not illustrated, the device may comprise further nips.

Further, as illustrated in FIGS. 4a-4e, the device 500, 500′ may comprise at least one support roll 53a, 53b, 53c, 53d.

As illustrated in FIG. 4a, 4d, 4e, the device 500, 500′, may comprise a first and a second support roll 53a, 53b.

As illustrated in FIG. 4c, the device 500 may comprise a first, a second, and a third support roll 53a, 53b, 53c, 53d.

As illustrated in FIG. 4b, the device 500 may comprise a first, a second, a third, and a fourth support roll 53a, 53b, 53c, 53d.

The device 500 as illustrated in FIG. 4a may be operated according to the following:

The running of the multilayer material 1 is started. For example, a continuous web of the multilayer material 1 may be passed from a material supply 100, such as an unwinding roll (not illustrated), via the support roll 53a, to the nip 6 defined by the cliché cylinder 52 and the milling cutter 51. The multilayer material 1 may then forced against the envelope surface of the cliché 52, by applying a tensile stress on the running material 1, such that at least the first layer 10 of the multilayer material 1 is shaped into a three-dimensional pattern of ridges and valleys.

The milling cutter 51 may then be started and the cutter speed may be set. The cliché cylinder 52 may rotate at a periphery velocity equal to the feeding velocity of the multilayer material, while the milling cutter 51 may rotate at a much higher periphery velocity. At this stage, the distance between the milling cutter 51 and the cliché cylinder 52 is so large that no milling is done. Once the speed is stabilized, the milling cutter 51 may be moved towards the cliché cylinder 52 and the running material 1. When the milling cutter 51 touches the multilayer material 1, the milling cutter 51 removes material from at least the top layer of the multilayer material 1 simultaneously with said shaping of the multilayer material.

In this first milling step, the cutting depth is set so that predetermined portions of the first layer 10 of the multilayer material 1 is removed partially, as seen in a thickness direction. The cutting depth can be monitored by one or several measuring methods, as described above.

After this first milling step, the partly formed multilayer material 1a may then be passed at least one more time through the nip 6. For example, the multilayer material 1a may be passed via the second support roll 53b and rolled onto a material winding roll (not illustrated). The multilayer material 1a may then be passed from said material winding roll, via the support roll 53a, to the nip 6. In such case, said material winding roll can be seen to form an unwinding roll from which the material is supplied to the nip 6.

The milling cutter 51 and patterned cliché cylinder 52 may be set to perform a subsequent milling step. The cutting depth may be set so that the milling cutter 51 operates with a larger cutting depth as compared with the first milling step. Further, the multilayer material 1a may be adjusted in an Y_{M}-direction (along a length of the material) and an X_{M}-direction (across the width of the material), see for example FIG. 5, so that the pattern obtained during the first milling step exactly matches the pattern that is created during the subsequent milling step.

The device 500 as illustrated in FIG. 4a, may be operated such that a first feed rate of the multilayer material 1 in the first milling step is the same, or different, as a second feed rate in the subsequent milling step. Further, the device 500 may be operated such that a first cutter speed of the first milling step is the same, or different, as a second cutter speed of the subsequent milling step.

After the subsequent milling step, the multilayer material 1b may have been provided with the desired pattern. The multilayer material 1b may then be passed via the second support roll 53b and rolled onto a material winding roll (not illustrated).

Although not illustrated, it is understood that more than two milling steps may be provided in order to produce the desired pattern.

A device 500′ according to FIGS. 4b, may be operated according to the following:

The running of the multilayer material 1 is started. For example, a continuous web of the multilayer material 1 may be passed from a material supply 100, such as an unwinding roll (not illustrated), via a first support roll 53a, to the first nip 6a. The material 1 may further be passed to the second nip 6b. The material may be passed to the second nip 6b via at least one support roll. As illustrated in FIG. 4b, the material may be passed via a second and a third support roll 53b, 53c to the second nip 6b.

The multilayer material 1 may be forced against the envelope surface of the first cliché 52a of the first nip 6a, by applying a tensile stress on the running material 1, such that at least the first layer 10 of the multilayer material 1 is shaped into a three-dimensional pattern of ridges and valleys.

Further, the multilayer material 1a may be forced against the envelope surface of the second cliché 52b of the second nip 6b, by applying a tensile stress on the running material 1, such that at least the first layer 10 of the multilayer material 1a is shaped into a three-dimensional pattern of ridges and valleys.

The multilayer material 1, 1a may be registered against the pattern of each cliché cylinder in both the Y_{M}-direction (along the length of the material) and in the X_{M}-direction (across the width of the material), see for example FIG. 5. Further, registration of the cliché cylinders relative one another in X-direction and Y-direction may be performed. In addition, a registration of a rotational angle θ of the cliché cylinders may also performed, see FIG. 6.

The milling cutters 51a, 51b may be started and the cutter speeds of the milling cutters 51a, 51b may be set. The cliché cylinders 52a, 52b may rotate at a periphery velocity equal to the feeding velocity of the multilayer material, while the milling cutters 51a, 51b may rotate at a much higher periphery velocity. At this stage, the distance between the milling cutters 51a, 51b and cliché cylinders 52a, 52b of each nip 6a, 6b is so large that no milling is done.

Once the speed is stabilized, the first milling cutter 51a of the first nip 6a may be moved towards the first cliché cylinder 52a of the first nip 6a and the running material 1. When the first milling cutter 51a of the first nip 6a touches the multilayer material 1, the first milling cutter 51a removes material at least from the top layer of the multilayer material 1 simultaneously with said shaping of the multilayer material. The cutting depth is set so that predetermined portions of the first layer 10 of the multilayer material 1 is removed partially, as seen in a thickness direction. The cutting depth can be monitored by one or several measuring methods, as described above.

Once the milling speed and cutting depth of the first milling cutter 51a is set, the second milling cutter 52b of the second nip 6b may be moved towards the second cliché cylinder 52b of the second nip 6b and the running material 1. The cutting depth may be set so that the second milling cutter 51b operates with a larger cutting depth as compared with the first cutter 51a. The cutting depth may be set so that a clear pattern appears. The cutting depth can be monitored by one or several measuring methods, as described above.

After the multilayer material has been passed through both the first and second nip 6a, 6b, the multilayer material 1b may have been provided with the desired pattern. The multilayer material 1b may then be passed via a fourth roll 53d and rolled onto a material winding roll (not illustrated).

Although not illustrated, it is understood that more than two milling steps may be provided in order to produce the desired pattern. Thus, if more than two nips 6a, 6b are used, the cutting depth of the second milling cutter 51b may be set so that predetermined portions of the first layer 10 of the multilayer material 1 is removed partially, as seen in a thickness direction. Thus, the second milling cutter 51b may mill down to a second cutting depth.

In a final nip, the material may be milled down to a cutting depth that makes a clear pattern appear.

A device 500′ according to FIGS. 4c, may be operated according to the following:

The running of the multilayer material 1 is started. For example, a continuous web of the multilayer material 1 may be passed from a material supply 100, such as an unwinding roll (not illustrated), via a first support roll 53a, to the first nip 6a. The material 1 may further be passed to the second nip 6b. The material may be passed to the second nip 6b via at least one support roll. As illustrated in FIG. 4c, the material may be passed via a second support roll 53b to the second nip 6b.

The multilayer material 1 may be forced against the envelope surface of the first cliché 52a of the first nip 6a, by applying a tensile stress on the running material 1, such that at least the first layer 10 of the multilayer material 1 is shaped into a three-dimensional pattern of ridges and valleys.

The multilayer material 1a may be forced against the envelope surface of the second cliché 52b of the second nip 6b, by applying a tensile stress on the running material 1, such that at least the first layer 10 of the multilayer material 1a is shaped into a three-dimensional pattern of ridges and valleys.

The multilayer material 1, 1a may be registered against the pattern of each cliché cylinder in both the Y_{M}-direction (along the length of the material) and in the X_{M}-direction (across the width of the material), see for example FIG. 5. Further, registration of the cliché cylinders relative one another in X-direction and Y-direction may be performed. In addition, a registration of a rotational angle θ of the cliché cylinders may also performed, see FIG. 6.

The milling cutter 51a may be started and the cutter speed of the milling cutter 51a may be set. The cliché cylinders 52a, 52b may rotate at a periphery velocity equal to the feeding velocity of the multilayer material, while the milling cutter 51a may rotate at a much higher periphery velocity. At this stage, the distance between the milling cutter 51a and the first cliché cylinder 52a is so large that no milling is done. Further, at this stage, the distance between the milling cutter 51a and the second cliché cylinder 52b is so large that no milling is done.

Once the speed is stabilized, the milling cutter 51a may be moved towards the first cliché cylinder 52a of the first nip 6a and the second cliché cylinder 52b of the second nip 6b, and the running material 1. Thus, the milling cutter 51a may be moved in the Y_{mc}-direction towards the first and second cliché cylinders 52a, 52b, as illustrated in FIG. 4c. Alternatively, the first cliché cylinder 52a and the second cliché cylinder 52b may be moved towards the milling cutter 51a. The milling cutter 51 may be adjusted in X_{mc}-direction to set a first cutting depth for the milling performed in the first nip 6a, and a second cutting depth for the milling performed in the second nip 6b.

When the milling cutter 51a touches the multilayer material 1 in the first nip 6a, the milling cutter 51a removes material from at least the top layer of the multilayer material 1 simultaneously with said shaping of the multilayer material. The cutting depth is set so that predetermined portions of the first layer 10 of the multilayer material 1 is removed partially, as seen in a thickness direction. The cutting depth can be monitored by one or several measuring methods, as described above.

In the second nip 6b, the cutting depth may be set so that the milling cutter 51a operates with a larger cutting depth as compared with the first nip 6a. Thus, the cutting depth may be set so that a clear pattern appears.

After the multilayer material has been passed through both the first and second nip 6a, 6b, the multilayer material 1b may have been provided with the desired pattern. The multilayer material 1b may then be passed via a third support roll 53c and rolled onto a material winding roll (not illustrated).

Although not illustrated, it is understood that more than two milling steps may be provided in order to produce the desired pattern. Thus, if more than two nips 6a, 6b are used, the cutting depth in the second nip 6b may be set so that predetermined portions of the first layer 10 of the multilayer material 1 is removed partially, as seen in a thickness direction. Thus, in the the second nip 6b, the milling cutter 51a may mill down to a second cutting depth. In a final nip, the material may be milled down to a cutting depth that makes a clear pattern appear.

A device 500′ according to FIGS. 4d, may be operated according to the following:

The running of the multilayer material 1 is started. For example, a continuous web of the multilayer material 1 may be passed from a material supply 100, such as an unwinding roll (not illustrated), via a first support roll 53a, to the first nip 6a and the second nip 6b.

The multilayer material 1, 1a may be forced against the envelope surface of the cliché cylinder 52a of the first nip 6a, by applying a tensile stress on the running material 1, such that at least the first layer 10 of the multilayer material 1 is shaped into a three-dimensional pattern of ridges and valleys.

The milling cutters 51a, 51b may be started and the cutter speeds of the milling cutters 51a, 51b may be set. The cliché cylinder 52a may rotate at a periphery velocity equal to the feeding velocity of the multilayer material, while the milling cutters 51a, 51b may rotate at a much higher periphery velocity. At this stage, the distance between the first and second milling cutters 51a, 51b and the first cliché cylinder 52a is so large that no milling is done.

Once the speed is stabilized, the first milling cutter 51a of the first nip 6a may be moved towards the first cliché cylinder 52a of the first nip 6a and the running material 1. When the first milling cutter 51a of the first nip 6a touches the multilayer material 1, the first milling cutter 51a removes material at least from the top layer of the multilayer material 1 simultaneously with said shaping of the multilayer material. The cutting depth is set so that predetermined portions of the first layer 10 of the multilayer material 1 is removed partially, as seen in a thickness direction. The cutting depth can be monitored by one or several measuring methods, as described above.

Once the milling speed and cutting depth of the first nip 6a is set, the second milling cutter 51b of the second nip 6b may be moved towards the cliché cylinder 52a of the second nip 6b and the running material 1. The cutting depth may be set so that the second milling cutter 51b operates with a larger cutting depth as compared with the first milling cutter 51a. Thus, the cutting depth may be set so that a clear pattern appears. The cutting depth can be monitored by one or several measuring methods, as described above.

After the multilayer material has been passed through both the first and second nip 6a, 6b, the multilayer material 1b may have been provided with the desired pattern. The multilayer material 1b may then be passed via a second roll 53b and rolled onto a material winding roll (not illustrated).

Although not illustrated, it is understood that more than two milling steps may be provided in order to produce the desired pattern. Thus, if more than two nips 6a, 6b are used, the cutting depth of the second milling cutter 51b may be set so that predetermined portions of the first layer 10 of the multilayer material 1 is removed partially, as seen in a thickness direction. Thus, the second milling cutter 51b may mill down to a second cutting depth. In a final nip, the material may be milled down to a cutting depth that makes a clear pattern appear.

A device 500′ according to FIGS. 4e, may be operated according to the following:

The running of the multilayer material 1 is started. For example, a continuous web of the multilayer material 1 may be passed from a material supply 100, such as an unwinding roll (not illustrated), via a first support roll 53a, to the first nip 6a and the second nip 6b.

The multilayer material 1 may be forced against the envelope surface of the cliché 52a, by applying a tensile stress on the running material 1, such that at least the first layer 10 of the multilayer material 1 is shaped into a three-dimensional pattern of ridges and valleys.

The milling cutters 51a, 51b may be started and the cutter speeds of the milling cutters 51a, 51b may be set. The cliché cylinder 52a may rotate at a periphery velocity equal to the feeding velocity of the multilayer material, while the milling cutters 51a, 51b may rotate at a much higher periphery velocity. At this stage, the distance between the first and second milling cutters 51a, 51b and the first cliché cylinder 52a is so large that no milling is done.

Once the cutter speeds are stabilized, the fixture 54 with the first and second milling cutters 51a, 51b may be moved towards the first cliché cylinder 52a and the running material 1. When the first milling cutter 51a touches the multilayer material 1, the first milling cutter 51a removes material at least from the top layer of the multilayer material 1 simultaneously with said shaping of the multilayer material. The cutting depth is set so that predetermined portions of the first layer 10 of the multilayer material 1 is removed partially, as seen in a thickness direction. The cutting depth can be monitored by one or several measuring methods, as described above.

When the second milling cutter 51b touches the multilayer material 1, the second milling cutter 51b may remove the remaining material, such that the desired pattern appears. The cutting depth may be set so that the second milling cutter 51b operates with a larger cutting depth as compared with the first milling cutter 51a. The cutting depth may set so that a clear pattern appears. The cutting depth can be monitored by one or several measuring methods, as described above. As have been described above, different cutting depths of the first and second milling cutters 51a, 51b may be achieved by adjusting their position relative one another in the fixture 54, such that an offset relative one another is provided.

After the multilayer material has been passed through both the first and second nip 6a, 6b, the multilayer material 1b may have been provided with the desired pattern. The multilayer material 1b may then be passed via the second support roll 53b and rolled onto a material winding roll (not illustrated).

Although not illustrated, it is understood that more than two milling steps may be provided in order to produce the desired pattern. Thus, if more than two nips 6a, 6b are used, the cutting depth of the second milling cutter 51b may be set so that predetermined portions of the first layer 10 of the multilayer material 1 is removed partially, as seen in a thickness direction. Thus, the second milling cutter 51b may mill down to a second cutting depth. In a final nip, the material may be milled down to a cutting depth that makes a clear pattern appear.

1. A method of producing a product comprising a substrate with at least one 2D-patterned layer from a multilayer material,
wherein the multilayer material is passed through at least one nip, provided by a milling cutter cooperating with a patterned cliché cylinder, to selectively remove predetermined portions of material from at least a first layer of the multilayer material in accordance with a pattern of the patterned cliché cylinder, whereby the 2D-patterned layer is formed from the first layer,
the method comprising:
providing the multilayer material comprising at least the first layer and a second layer,
feeding the multilayer material through a first such nip to partially, as seen in a thickness direction of the first layer, remove at least some of the predetermined portions of material from at least the first layer, and
feeding the multilayer material through a second such nip to remove a remainder of said at least some of the predetermined portions of material.

2. The method according to claim 1, wherein said first and second nip is formed by a patterned cliché cylinder and a milling cutter, wherein the multilayer material is passed by the patterned cliché cylinder and the milling cutter at least two times to perform at least a first milling step and a subsequent milling step.

3-4. (canceled)

5. The method according to claim 1, wherein the first nip is formed by a first patterned cliché cylinder and a first milling cutter, and wherein the second nip is formed by a second patterned cliché cylinder and a second milling cutter.

6. The method according to claim 1, wherein the first nip is formed by a first patterned cliché cylinder and a first milling cutter, and wherein the second nip is formed by a second patterned cliché cylinder and the first milling cutter.

7. The method according to claim 1, wherein the first nip is formed by a first patterned cliché cylinder and a first milling cutter, and wherein the second nip is formed by the first patterned cliché cylinder and a second milling cutter.

8-9. (canceled)

10. The method according to claim 1, wherein in a first milling step, the multilayer material is passed through said first nip and in a subsequent milling step, the multilayer material is passed through said second nip.

11. The method according to claim 1, wherein, in the first nip, the milling cutter is set to operate with a first cutting depth, and in the second nip, the milling cutter (51, 51a, 51b) is set to operate with a second cutting depth, wherein the second cutting depth is larger than the first cutting depth.

12-13. (canceled)

14. The method according to claim 1, wherein the method comprises, when feeding the material through the first nip, forming at least one groove in the first layer.

15. The method according to claim 1, wherein the multilayer material is a flexible material, such as a foil or a film.

16. (canceled)

17. The method according to claim 1, wherein the first layer is a conductive layer.

18. The method according to claim 1, wherein the first layer is formed of one or several metals, a metal alloy or a polymer.

19. (canceled)

20. The method according to claim 1, wherein the first layer has a thickness of about 5-150 μm, 5-100 μm, 5-75 μm, 5-40 μm, 9-30 μm or 10-20 μm.

21. (canceled)

22. The method according to claim 1, wherein the first layer has a machinability value, measured as specific cutting force, of more than 300 N/mm².

23. (canceled)

24. The method according to claim 1, wherein the second layer is formed of a dielectric material. 25-26. (canceled)

27. The method according to claim 1, wherein the multilayer material comprises a cover layer covering at least a portion of a first surface of the first layer.

28-29. (canceled)

30. The method according to claim 1, wherein the multilayer material comprises at least one additional conductive layer. 31-35. (canceled)

36. A device for producing a product comprising a substrate with at least one 2D-patterned layer from a multilayer material, the device comprising:
at least one milling cutter configured to cooperate with at least one patterned cliché cylinder to form a nip, for selectively removing predetermined portions of material from at least a first layer of the multilayer material in accordance with a pattern of the patterned cliché cylinder, so as to form the 2D-patterned layer from the first layer,
the device is configured such that it, in use, provides a first such nip for removing partially, as seen in a thickness direction of the first layer, at least some of the predetermined portions of material from at least the first layer, and
the device is configured such that it, in use, provides a second such nip for removing a remainder of said at least some of the predetermined portions of material.

37. The device according to claim 36, wherein the first nip is formed by a first patterned cliché cylinder and a first milling cutter, and the second nip is formed by the first patterned cliché cylinder and a second milling cutter.

38-40. (canceled)

41. The device according to claim 36, wherein the first nip is formed by a first milling cutter and a first patterned cliché cylinder, and the second nip is formed by a second milling cutter and a second patterned cliché cylinder.

42. The device according to claim 36, wherein the first nip (6a) is formed by a first milling cutter and a first patterned cliché cylinder, and the second nip is formed by the first milling cutter and a second patterned cliché cylinder.

43-44. (canceled)
